(19) United States
(12) Patent Application Publication
(10) Pub. No.: US 2025/0063885 A1
(43) Pub. Date: Feb. 20, 2025

(54) LIGHT EMITTING ELEMENT, INK COMPOSITION AND DISPLAY DEVICE INCLUDING THE LIGHT EMITTING ELEMENT

(71) Applicant: Samsung Display Co., LTD., Yongin-si (KR)

(72) Inventors: YUNKU JUNG, Yongin-si (KR); SOOHO LEE, Yongin-si (KR); Jungho JO, Yongin-si (KR); Chang Yeol HAN, Yongin-si (KR); YUNHYUK KO, Yongin-si (KR); SEHUN KIM, Yongin-si (KR)

(21) Appl. No.: 18/750,963

(22) Filed: Jun. 21, 2024

(30) Foreign Application Priority Data
Aug. 16, 2023 (KR) 10-2023-0107220

(51) Int. Cl. H10K 50/16; C09D 11/037; C09K 11/06; H10K 50/115; H10K 50/165; H10K 85/30

(52) U.S. Cl. CPC H10K 50/167; C09D 11/037; C09K 11/06; H10K 50/115; H10K 50/165; H10K 85/30; C09K 2211/188

(57) ABSTRACT

A light emitting element of an embodiment includes a first electrode, a hole transport region on the first electrode, an emission layer on the hole transport region, an electron transport region on the emission layer, and a second electrode on the electron transport region, the electron transport region includes a nanoparticle including a nanoparticle core and a ligand, the nanoparticle core includes a core compound represented by Formula 1, and the ligand is bonded to the surface of the nanoparticle core and represented by Formula 2 or Formula 3.

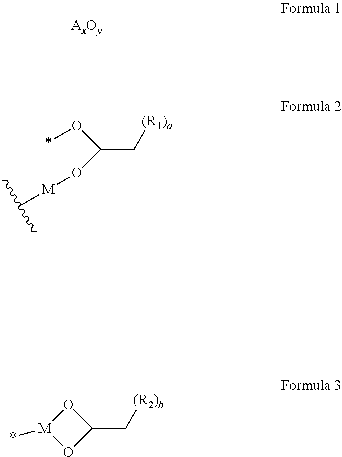

### CROSS-REFERENCE TO RELATED APPLICATIONS

The present application claims priority to and the benefit of Korean Patent Application No. 10-2023-0107220, filed on Aug. 16, 2023, in the Korean Intellectual Property Office, the entire content disclosure of which is hereby incorporated by reference.

### BACKGROUND

### 1. Field

Embodiments of the present disclosure herein relate to a light emitting element, an ink composition, and a display device including the light emitting element and, for example, to a light emitting element having improved emission efficiency and element lifetime, and a display device including the same.

### 2. Description of the Related Art

Recently, the development of an organic electroluminescence display as an image display for an image display device is being actively conducted. The organic electroluminescence display is different from a liquid crystal display and is a so-called self-luminescent display device in which holes and electrons injected from a first electrode and a second electrode recombine in an emission layer so that a light emitting material including an organic compound in the emission layer emits light to achieve a display.

In the application of an organic electroluminescence light emitting element to a display device, the increase of emission efficiency and lifetime is useful, and development of materials for a light emitting element that stably achieve desirable features is being consistently investigated.

To provide a light emitting element having high efficiency and long lifetime, development of a material for an electron transport region having excellent electron transport properties and stability is being conducted.

### SUMMARY

An object of embodiments of the present disclosure is to provide a light emitting element having improved emission efficiency and element lifetime.

Another object of embodiments of the present disclosure is to provide an ink composition which is capable of improving the emission properties and the element lifetime of a light emitting element.

Another object of embodiments of the present disclosure is to provide a display device including a light emitting element having improved emission efficiency and element lifetime.

A light emitting element according to an embodiment of the present disclosure includes a first electrode, a hole transport region on the first electrode, an emission layer on the hole transport region, an electron transport region on the emission layer, and a second electrode on the electron transport region, wherein the electron transport region includes a nanoparticle including a nanoparticle core and a ligand, the nanoparticle core includes a core compound represented by Formula 1, and the ligand is bonded to a surface of the nanoparticle core and represented by Formula 2 or Formula 3.

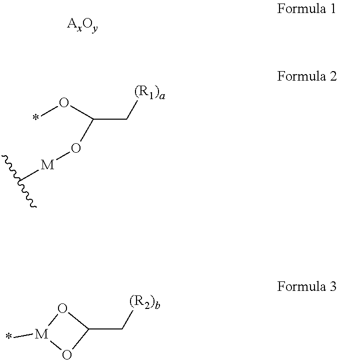

In Formula 1, A is Zn, or Sn, and “x”, and “y” are each independently an integer of 1 to 5, in Formula 2, M is one among Li, Na, K, Rb, Cs, Be, Ca, Sr, and Ba, R₁ is a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, “a” is an integer of 0 to 3, and “ [symbol] ”, and

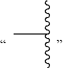

are each a position connected with the nanoparticle core, and in Formula 3, R₂ is a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, M is the same as defined in Formula 2, “b” is an integer of 0 to 3, and “ [symbol] ” is a position connected with the nanoparticle core.

In an embodiment, the electron transport region may include an electron transport layer on the emission layer, and an electron injection layer on the electron transport layer, and the electron transport layer may include the nanoparticle.

In an embodiment, the nanoparticle core may be doped with a metal element.

In an embodiment, the metal element may be at least one among Zn, Mg, Li, Na, Ni, and Cu.

In an embodiment, the emission layer may include a quantum dot.

In an embodiment, in Formula 1, “x” may be 1, and “y” may be 2.

In an embodiment, in Formula 1, “a” may be Sn, and in Formula 2 and Formula 3, M may be Ca.

In an embodiment, if the ligand is represented by Formula 2, R₁ may be a substituted or unsubstituted alkyl group of 1 to 5 carbon atoms, and if the ligand is represented by Formula 3, R₂ may be a substituted or unsubstituted alkyl group of 1 to 5 carbon atoms.

In an embodiment, if the ligand is represented by Formula 2, R₁ may be a substituted or unsubstituted alkyl group of 6 to 20 carbon atoms, and if the ligand is represented by Formula 3, R₂ may be a substituted or unsubstituted alkyl group of 6 to 20 carbon atoms.

An ink composition according to an embodiment of the present disclosure includes a nanoparticle core including a core compound represented by Formula 1, a preliminary ligand represented by Formula 4, and a solvent in which the nanoparticle core and the preliminary ligand are dispersed.

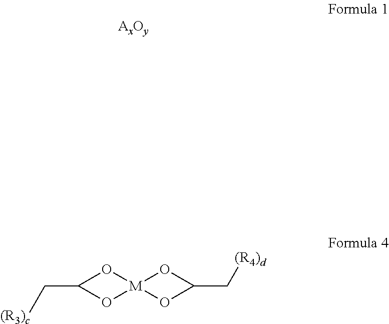

In Formula 1, A is Zn, or Sn, and “x”, and “y” are each independently an integer of 1 to 5, in Formula 4, M is one among Li, Na, K, Rb, Cs, Be, Ca, Sr, and Ba, R₃ and R₄ are each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and “c” and “d” are each independently an integer of 0 to 3.

In an embodiment, in Formula 4, R₃ and R₄ may be each independently a substituted or unsubstituted alkyl group of 1 to 5 carbon atoms.

In an embodiment, the solvent may include a water-soluble solvent.

In an embodiment, a weight ratio of the nanoparticle core to the water-soluble solvent may be about 1% to about 10%.

In an embodiment, the water-soluble solvent may include a first solvent compound represented by Formula 5.

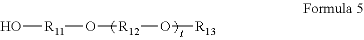

In Formula 5, R₁₁ and R₁₂ are each independently a substituted or unsubstituted alkylene group of 1 to 4 carbon atoms, R₁₃ is a substituted or unsubstituted alkyl group of 1 to 4 carbon atoms, and “t” is 1 or 2.

In an embodiment, the first solvent compound may include at least one among diethylene glycol t-butyl ether (DGtBE), tripropylene glycol monobutyl ether (TPGBE), and triethylene glycol monoisopropyl ether (TGIPE).

In an embodiment, in Formula 4, R₃ and R₄ may be each independently a substituted or unsubstituted alkyl group of 6 to 20 carbon atoms.

In an embodiment, the solvent may include at least one among cyclohexylbenzene (CHB) and hexadecane.

A display device according to an embodiment of the present disclosure includes a base layer, a circuit layer on the base layer, and a display element layer on the circuit layer and including a light emitting element, wherein the light emitting element includes a first electrode, a second electrode on the first electrode, and an electron transport region between the first electrode and the second electrode, the electron transport region includes a nanoparticle including a nanoparticle core and a ligand, the nanoparticle core includes a core compound represented by Formula 1, and the ligand is bonded to a surface of the nanoparticle core and represented by Formula 2 or Formula 3.

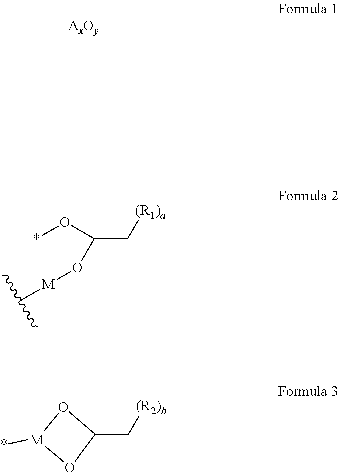

In Formula 1, A is Zn, or Sn, and “x”, and “y” are each independently an integer of 1 to 5, in Formula 2, M is one among Li, Na, K, Rb, Cs, Be, Ca, Sr, and Ba, R₁ is a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, “a” is an integer of 0 to 3, and “ [symbol] ”, and

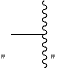

are each a position connected with the nanoparticle core, and in Formula 3, R₂ is a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, M is the same as defined in Formula 2, “b” is an integer of 0 to 3, and “ [symbol] ” is a position connected with the nanoparticle core.

In an embodiment, the light emitting element may further include a hole transport region on the first electrode, and an emission layer between the hole transport region and the electron transport region, and the emission layer may include a quantum dot.

In an embodiment, the electron transport region may include an electron transport layer on the emission layer, and an electron injection layer on the electron transport layer, and the electron transport layer may include the nanoparticle.

### BRIEF DESCRIPTION OF THE DRAWINGS

The accompanying drawings are included to provide a further understanding of the subject matter of the present disclosure and are incorporated in and constitute a part of this specification. The drawings illustrate embodiments of the present disclosure and, together with the description, serve to explain principles of embodiments of the present disclosure. In the drawings:

FIG. 1 is a perspective view showing a display device of an embodiment;

FIG. 2 is a cross-sectional view showing a part corresponding to line I-I′ in FIG. 1;

FIG. 3 is a plan view showing a display device of an embodiment;

FIG. 4 is a cross-sectional view showing a part corresponding to line II-II′ in FIG. 3;

FIG. 5 is a cross-sectional view showing a light emitting element according to an embodiment;

FIG. 6 is a diagram showing a portion of an ink composition according to an embodiment; and

FIG. 7 and FIG. 8 are diagrams showing portions of nanoparticles according to embodiments.

### DETAILED DESCRIPTION

The subject matter of the present disclosure may have various modifications and may be embodied in different forms, and example embodiments will be explained in more detail with reference to the accompany drawings. The subject matter of the present disclosure may, however, be embodied in different forms and should not be construed as limited to the embodiments set forth herein. Rather, all modifications, equivalents, and substituents which are included in the spirit and technical scope of the present disclosure should be included in the scope of the present disclosure.

In the description, when an element (or a region, a layer, a part, etc.) is referred to as being “on”, “connected with” or “combined with” another element, it can be directly on/connected with/bonded to the other element, or intervening third elements may also be provided.

Like reference numerals refer to like elements throughout. In the drawings, the thicknesses, ratios, and dimensions of elements may be exaggerated for effective explanation of technical contents. “and/or” may include one or more combinations that may define relevant elements.

It will be understood that, although the terms first, second, etc. may be used herein to describe various elements, these elements should not be limited by these terms. These terms are only used to distinguish one element from another element. For example, a first element could be termed a second element without departing from the scope of the present disclosure. Similarly, a second element could be termed a first element. As used herein, the singular forms are intended to include the plural forms as well, unless the context clearly indicates otherwise.

In embodiments, the terms “below”, “beneath”, “on” and “above” are used for explaining the relation of elements shown in the drawings. The terms are relative concepts and are explained based on the direction shown in the drawing, but the present disclosure is not limited thereto.

It will be further understood that the terms “comprises” or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this disclosure belongs. In embodiments, it will be further understood that terms, such as those defined in commonly used dictionaries, should be interpreted as having a meaning that is consistent with their meaning in the context of the relevant art and will not be interpreted in an idealized or overly formal sense unless expressly defined so herein.

In the description, the term “substituted or unsubstituted” corresponds to substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In embodiments, each of the exemplified substituents may be substituted or unsubstituted. For example, a biphenyl group may be interpreted as an aryl group or a phenyl group substituted with a phenyl group.

In the description, an alkyl group may be a linear, or branched type (e.g., a linear or branched alkyl group). The carbon number of the alkyl group may be 1 to 60, 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, an alkoxy group may include the above-defined alkyl group which is combined with an oxygen atom. The alkoxy group may be a linear, branched or cyclic chain alkoxy group. The carbon number of the alkoxy group is not specifically limited but may be, for example, 1 to 30, 1 to 20, 1 to 10, or 1 to 5.

Examples of the alkoxy group may include methoxy, ethoxy, n-propoxy, isopropoxy, butoxy, pentyloxy, hexyloxy, octyloxy, nonyloxy, decyloxy, etc. However, an embodiment of the present disclosure is not limited thereto.

In the description, the carbon number of an amine group is not specifically limited, but may be 1 to 30, 1 to 20, or 1 to 10. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, etc., without limitation.

In the description, a direct linkage may mean a single bond (e.g., a single covalent bond).

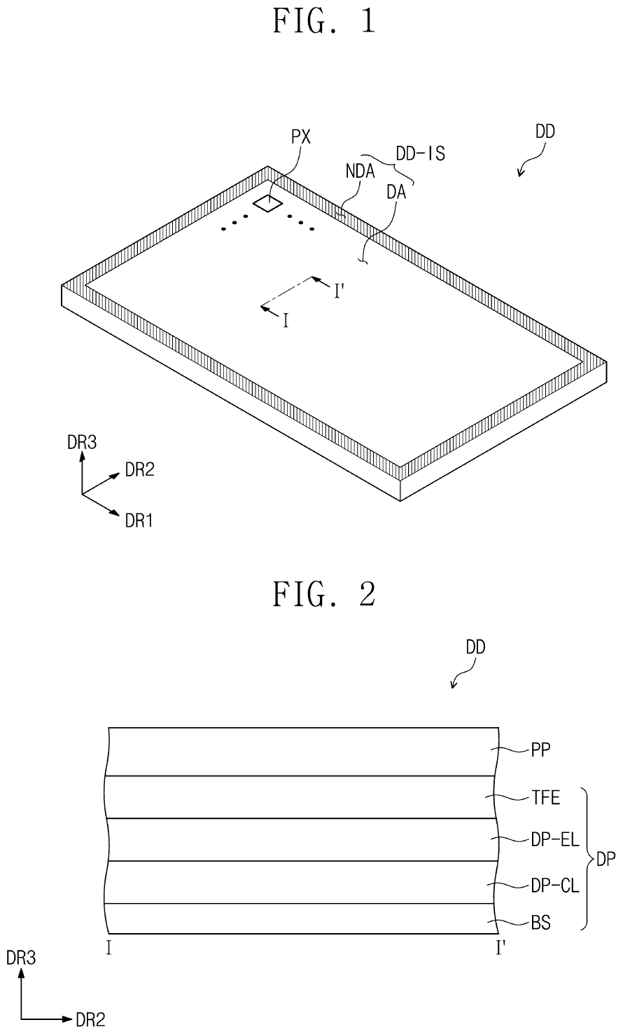

Hereinafter, a light emitting element according to an embodiment of the present disclosure and a display device including the light emitting element will be explained by referring to the drawings. FIG. 1 is a perspective view showing a display device of an embodiment.

Referring to FIG. 1, the display device DD of an embodiment may be a device activated by electrical signals. For example, the display device DD may be a large-sized device such as a television, a monitor and/or an external billboard. In embodiments, the display device DD may be small-and/or medium-sized devices such as a personal computer, a laptop computer, a personal digital terminal, a car navigation unit, a game console, a smart phone, a tablet and/or a camera. The foregoing are suggested only as examples, and the display device DD may be employed as other electronic devices unless it deviates from the present disclosure.

The display device DD may display images (or videos) through a display surface DD-IS. The display surface DD-IS may be parallel to a plane defined by a first direction DR1 and a second direction DR2. The display surface DD-IS may include a display area DA and a non-display area NDA.

In the display area DA, a pixel PX may be provided, and in the non-display area NDA, the pixel PX may not be provided. The non-display area NDA may be defined along the edge of the display surface DD-IS. The non-display area NDA may surround the display area DA. However, an embodiment of the present disclosure is not limited thereto, and the non-display area NDA may be omitted, or the non-display area NDA may be provided only at one side of the display area DA.

In FIG. 1, a display device DD provided with a planar display surface DD-IS is shown, but an embodiment of the present disclosure is not limited thereto. The display device DD may include a curve-type display surface or a three-dimensional display surface. The three-dimensional display surface may include a plurality of display areas indicating other directions from each other.

In FIG. 1 and the drawings below, a first directional axis DR1 to a third directional axis DR3 are shown, and the directions indicated by the first to third directional axes DR1, DR2 and DR3, explained in the description are relative concepts and may be converted to other directions. In embodiments, the directions indicated by the first to third directional axes DR1, DR2 and DR3 may be explained as a first to third directions, and the same reference symbols may be used. In the description, the first directional axis DR1 and the second directional axis DR2 may be orthogonal to each other, and the third directional axis DR3 may be the normal direction to a plane defined by the first directional axis DR1 and the second directional axis DR2. In the description, the term “plane” means a plane defined by the first directional axis DR1 and the second directional axis DR2, the term “cross-section” may mean a surface perpendicular to the plane defined by the first directional axis DR1 and the second directional axis DR2 and parallel to the third directional axis DR3. The thickness direction of the display device DD may be a direction parallel to the third direction DR3 that is a normal direction to the plane defined by the first direction DR1 and the second direction DR2.

In the description, the top surface (or front surface) and bottom surface (or rear surface) of the members constituting the display device DD may be defined based on the third direction DR3. In embodiments, for one element, a surface relatively adjacent to the display surface DD-IS among two facing surfaces (e.g., opposing surfaces) based on the third direction DR3 may be defined as the front surface (or top surface), and a surface relatively separated apart from (e.g., facing away from) the display surface DD-IS may be defined as the rear surface (or bottom surface). In the description, an upper part (or upper side) or a lower part (or lower side) may be defined based on the third direction DR3, and the upper part (or upper side) may be defined as a direction close to the display surface DD-IS, and the lower part (lower side) may be defined as a direction away from the display surface DD-IS.

In the description, a statement that one element is “directly on/formed directly on” another element, may mean that there are no third elements between the one element and another element. For example, a statement that one element is “directly on/formed directly on” another element, may mean that the one element and another element make “contact” with each other.

FIG. 2 is a cross-sectional view showing a part corresponding to line I-I′. FIG. 2 may be a cross-sectional view of a display device according to an embodiment.

The display device DD may include a display panel DP and an optical layer PP on the display panel DP. The display panel DP may include a base layer BS, a circuit layer DP-CL on the base layer BS, a display element layer DP-EL on the circuit layer DP-CL, and an encapsulating layer TFE on the display element layer DP-EL.

The display panel DP may be an element that substantially produces images. The display panel DP may be an emission-type display panel. For example, the display panel DP may be a quantum dot emission display panel including a quantum dot light emitting element.

The base layer BS may be a member that provides a base surface for the circuit layer DP-CL. The base layer BS may be a rigid substrate or a flexible substrate of which bending, folding, rolling, and/or the like is possible. The base layer BS may be a glass substrate, a metal substrate and/or a polymer substrate. However, an embodiment of the present disclosure is not limited thereto, and the base layer BS may be an inorganic layer, an organic layer or a composite material layer (e.g., including an inorganic material and an organic material).

The circuit layer DP-CL may be on the base layer BS. The circuit layer DP-CL may include an insulating layer (e.g., an electrically insulating layer), a semiconductor pattern, a conductive pattern (e.g., an electrically conductive pattern), and a signal line. After forming an insulating layer (e.g., an electrically insulating layer), a semiconductor layer and a conductive layer (e.g., an electrically conductive layer) on the base layer BS by a method of coating, depositing, and/or the like, the insulating layer, semiconductor layer and conductive layer may be selectively patterned through multiple photolithography processes. After that, a semiconductor pattern, a conductive pattern (e.g., an electrically conductive pattern), and a signal line, included in the circuit layer DP-CL may be formed.

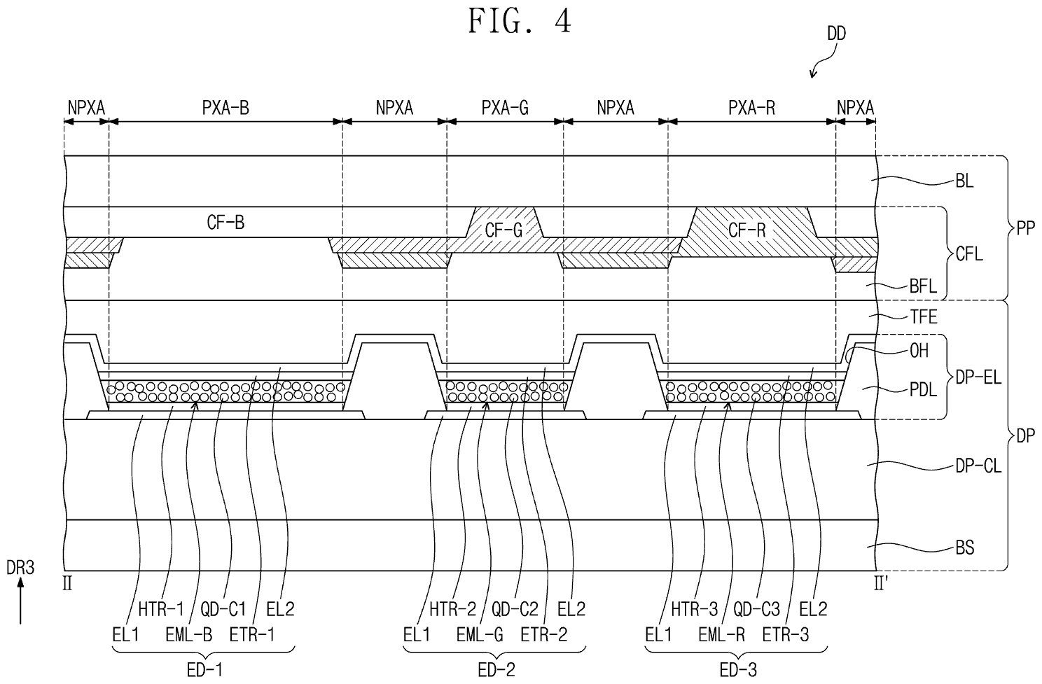

The display element layer DP-EL may be on the circuit layer DP-CL. The display element layer DP-EL may include a pixel definition layer PDL (FIG. 4), and first to third light emitting elements ED-1, ED-2 and ED-3 (FIG. 4), which will be further explained below. For example, the display element layer DP-EL may include an organic light emitting material, an inorganic light emitting material, an organic-inorganic light emitting material, a quantum dot, a quantum rod, a micro LED, and/or a nano LED. In embodiments, the display element layer DP-EL may include a quantum dot.

The encapsulating layer TFE may protect the display element layer DP-EL from foreign materials such as moisture, oxygen and/or dust particles. The encapsulating layer TFE may include at least one inorganic layer. The encapsulating layer may include a stacked structure of an inorganic layer, an organic layer and an inorganic layer, in order.

The optical layer PP may be on the display panel DP and may control reflected light at the display panel DP by external light. The optical layer PP may include, for example, a polarization layer and/or a color filter layer CFL (FIG. 4). In embodiments, the optical layer PP may be omitted.

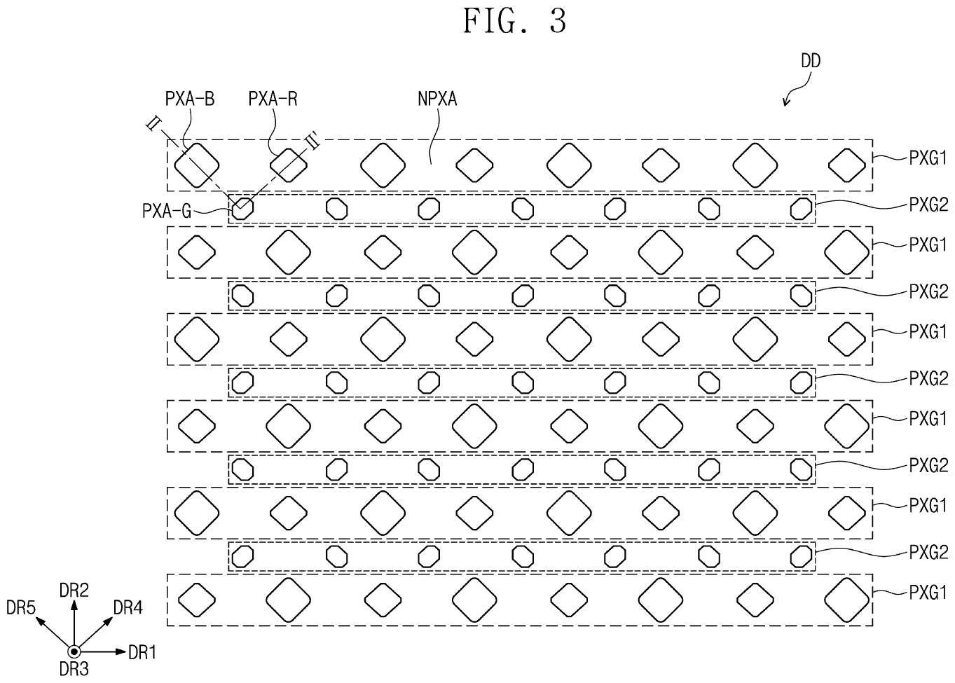

FIG. 3 is a plan view showing a display device of an embodiment. FIG. 4 is a cross-sectional view showing a part corresponding to line II-II′ in FIG. 3. FIG. 4 may be a cross-sectional view showing a display device of an embodiment.

Referring to FIG. 3 and FIG. 4, a display device DD may include a peripheral area NPXA and light emitting areas PXA-R, PXA-G and PXA-B. The light emitting areas PXA-R, PXA-G and PXA-B may be areas that emit light produced from the light emitting elements ED-1, ED-2 and ED-3, respectively. The areas of the light emitting areas PXA-R, PXA-G and PXA-B may be different from each other, and in embodiments, the term “area” may mean an area on a plane.

The light emitting areas PXA-R, PXA-G and PXA-B may be divided into a plurality of groups according to the color of light produced from the light emitting elements ED-1, ED-2 and ED-3. In FIG. 3 and FIG. 4, three light emitting areas PXA-R, PXA-G and PXA-B that emit red light, green light and blue light are illustrated as an embodiment. For example, the display device DD of an embodiment may include a red light emitting area PXA-R, a green light emitting area PXA-G and a blue light emitting area PXA-B, which are divided from each other.

The display panel DP may include a plurality of light emitting elements ED-1, ED-2 and ED-3 that emit light having different wavelength regions from each other. The plurality of light emitting elements ED-1, ED-2 and ED-3 may emit light of different colors from each other. For example, the display panel DP may include a first light emitting element ED-1 that emits red light, a second light emitting element ED-2 that emits green light, and a third light emitting element ED-3 that emits blue light. However, an embodiment of the present disclosure is not limited thereto, and the first to third light emitting elements ED-1, ED-2 and ED-3 may emit light in the same wavelength region, or at least one thereof may emit light in a different wavelength region.

In the display device DD of an embodiment, shown in FIG. 3 and FIG. 4, the light emitting areas PXA-R, PXA-G and PXA-B may have different areas according to the color emitted from the emission layers EML-B, EML-G and EML-R of the light emitting elements ED-1, ED-2 and ED-3. The blue light emitting area PXA-B of the first light emitting element ED-1, that emits blue light may have the largest area, the green light emitting area PXA-G of the second light emitting element ED-2, that emits green light may have the smallest area. However, an embodiment of the present disclosure is not limited thereto, and the light emitting areas PXA-R, PXA-G and PXA-B may emit light of a color different from red light, green light and blue light. Otherwise, the light emitting areas PXA-R, PXA-G and PXA-B may have the same area, or the light emitting areas PXA-R, PXA-G and PXA-B may be provided with an area ratio different from that shown in FIG. 3.

Each of the light emitting areas PXA-R, PXA-G and PXA-B may have an area divided by (or defined by) a pixel definition layer PDL. The peripheral areas NPXA may be areas between neighboring light emitting areas PXA-R, PXA-G and PXA-B and may be an area corresponding to the pixel definition layer PDL. Each of the light emitting areas PXA-R, PXA-G and PXA-B may correspond to a pixel.

The pixel definition layer PDL may define the light emitting areas PXA-R, PXA-G and PXA-B. The light emitting areas PXA-R, PXA-G and PXA-B and the peripheral area NPXA may be divided by (or defined by) the pixel definition layer PDL.

The blue light emitting areas PXA-B and the red light emitting areas PXA-R may be provided by turns along a first directional axis DR1 to form a first group PXG1. The green light emitting areas PXA-G may be provided along the first directional axis DR1 to form a second group PXG2. The first group PXG1 may be separately provided in the second directional axis DR2 with respect to the second group PXG2. A plurality of first groups PXG1 and a plurality of second groups PXG2 may be provided. The first groups PXG1 and the second groups PXG2 may be provided by turns in the second directional axis DR2.

One red light emitting area PXA-R may be separately provided in a fourth directional axis DR4 from one green light emitting area PXA-G. One blue light emitting area PXA-B may be separately provided in a fifth directional axis DR5 from one green light emitting area PXA-G. The fourth directional axis DR4 may be a direction between the first directional axis DR1 and the second directional axis DR2. The fifth directional axis DR5 may be a direction crossing the fourth directional axis DR4 and tilted with respect to the second directional axis DR2.

In embodiments, the arrangement structure of the light emitting areas PXA-R, PXA-G and PXA-B is not limited to the arrangement structure shown in FIG. 3. For example, in the light emitting areas PXA-R, PXA-G and PXA-B, the red light emitting area PXA-R, the green light emitting area PXA-G and the blue light emitting area PXA-B may be provided by turns along the first directional axis DR1. In embodiments, on a plane, the shapes of the light emitting areas PXA-R, PXA-G and PXA-B are not limited to those shown in the drawing, and may be defined into shapes different from those shown in the drawing.

In FIG. 4, the base layer BS may include a single layer or a multilayer structure. For example, the base layer BS may include a first synthetic resin layer, an interlayer of a multilayer or a single layer structure, and a second synthetic resin layer. The interlayer may also be referred to as a base barrier layer. The interlayer may include a silicon oxide (SiOₓ, x may be a real number between 0 and 2) layer and/or an amorphous silicon (a-Si) layer on the silicon oxide layer, but an embodiment of the present disclosure is not specifically limited thereto. For example, the interlayer may include at least one among a silicon oxide layer, a silicon nitride layer, a silicon oxynitride layer, and an amorphous silicon layer.

Each of the first and second synthetic resin layers may include a polyimide-based resin. In embodiments, each of the first and second synthetic resin layers may include at least one among an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin and a perylene-based resin. In the description, “ [symbol] ”-based resin means a resin including the functional group of “ [symbol] ”.

The circuit layer DP-CL may be on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2 and ED-3 of the display element layer DP-EL.

The display element layer DP-EL may include the pixel definition layer PDL and the first to third light emitting elements ED-1, ED-2 and ED-3. In the pixel definition layer PDL, a pixel opening part OH may be defined. The pixel definition layer PDL may divide the first to third light emitting elements ED-1, ED-2 and ED-3. The emission layers EML-R, EML-G and EML-B of the first to third light emitting elements ED-1, ED-2 and ED-3 may be provided and divided in the pixel opening part OH defined in the pixel definition layer PDL.

The pixel definition layer PDL may be formed using a polymer resin. For example, the pixel definition layer PDL may be formed by including a polyacrylate-based resin and/or a polyimide-based resin. In embodiments, the pixel definition layer PDL may be formed by further including an inorganic material in addition to the polymer resin. In embodiments, the pixel definition layer PDL may be formed by including a light absorption material and/or formed by including a black pigment and/or a black dye. The pixel definition layer PDL formed by including a black pigment and/or a black dye may provide a black pixel definition layer. Carbon black, and/or the like may be used as the black pigment and/or the black dye during forming the pixel definition layer PDL, but an embodiment of the present disclosure is not limited thereto.

In embodiments, the pixel definition layer PDL may be formed using an inorganic material. For example, the pixel definition layer PDL may be formed using an inorganic material including silicon nitride (SiN_{y}), silicon oxide (SiOₓ), silicon oxynitride (SiOₓN_{y}), and/or the like. x may be a real number between 0 and 2. y may be a real number between 0 and 4/3. For example, x is 0.5, y is 1.

The light emitting elements ED-1, ED-2 and ED-3 may include a first electrode EL1, hole transport regions HTR-1, HTR-2 and HTR-3 on the first electrode EL1, emission layers EML-B, EML-G and EML-R on the hole transport regions HTR-1, HTR-2 and HTR-3, electron transport regions ETR-1, ETR-2 and ETR-3 on the emission layers EML-B, EML-G and EML-R, and a second electrode EL2 on the electron transport regions ETR-1, ETR-2 and ETR-3.

The first electrode EL1 may be exposed at the pixel opening part OH of the pixel definition layer PDL. The first electrode EL1 has conductivity (e.g., electrical conductivity). The first electrode EL1 may be formed using a metal material, a metal alloy and/or a conductive compound (e.g., an electrically conductive compound). The first electrode EL1 may be a cathode or an anode. However, an embodiment of the present disclosure is not limited thereto. In embodiments, the first electrode EL1 may be a pixel electrode. The first electrode EL1 may be a transmissive electrode, a transflective electrode, or a reflective electrode. The first electrode EL1 may include at least one selected among Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, or oxides thereof.

If the first electrode EL1 is a transmissive electrode, the first electrode EL1 may include a transparent metal oxide, for example, indium tin oxide (ITO), indium zinc oxide (IZO), zinc oxide (ZnO), indium tin zinc oxide (ITZO), and/or the like. If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, compounds thereof, or mixtures thereof (for example, a mixture of Ag and Mg). In embodiments, the first electrode EL1 may have a structure including a plurality of layers including a reflective layer or a transflective layer formed using the above materials, and a transmissive conductive layer formed using ITO, IZO, ZnO, and/or ITZO. For example, the first electrode EL1 may have a three-layer structure of ITO/Ag/ITO, without limitation. In embodiments, the first electrode EL1 may include the above-described metal materials, combinations of two or more metal materials selected from the above-described metal materials, and/or oxides of the above-described metal materials. However, an embodiment of the present disclosure is not limited thereto. The thickness of the first electrode EL1 may be from about 700 Å to about 10,000 Å. For example, the thickness of the first electrode EL1 may be from about 1,000 Å to about 3,000 Å.

The second electrode EL2 may be a common electrode. The second electrode EL2 may be an anode or a cathode, but an embodiment of the present disclosure is not limited thereto. For example, if the first electrode EL1 is an anode, the second cathode EL2 may be a cathode, and if the first electrode EL1 is a cathode, the second electrode EL2 may be an anode. The second electrode EL2 may include at least one selected among Ag, Mg, Cu, Al, Pt, Pd, Au, Ni, Nd, Ir, Cr, Li, Ca, LiF, Mo, Ti, W, In, Sn, and Zn, compounds of two or more selected therefrom, mixtures of two or more selected therefrom, or oxides thereof.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, compounds including thereof, or mixtures thereof (for example, AgMg, AgYb, and/or MgYb). In embodiments, the second electrode EL2 may have a multilayered structure including a reflective layer or a transflective layer formed using the above-described materials and a transparent conductive layer formed using ITO, IZO, ZnO, ITZO, etc. For example, the second electrode EL2 may include the aforementioned metal materials, combinations of two or more metal materials selected from the aforementioned metal materials, and/or oxides of the aforementioned metal materials.

In embodiments, the second electrode EL2 may be connected with an auxiliary electrode. If the second electrode EL2 is connected with the auxiliary electrode, the resistance (e.g., electrical resistance) of the second electrode EL2 may decrease.

Between the first electrode EL1 and the second electrode EL2, emission layers EML-B, EML-G and EML-R may be provided. The first light emitting element ED-1 may include the first emission layer EML-B, the second light emitting element ED-2 may include the second emission layer EML-G, and the third light emitting element ED-3 may include the third emission layer EML-R. The first emission layer EML-B may include a first quantum dot QD-C1. The second emission layer EML-G may include a second quantum dot QD-C2. The third emission layer EML-R may include the third quantum dot QD-C3.

The quantum dots QD-C1, QD-C2 and QD-C3 included in the emission layers EML-B, EML-G and EML-R may be stacked to form layers. In FIG. 4, quantum dots QD-C1, QD-C2 and QD-C3 having a circular shape cross-section are provided to form roughly two layers as an embodiment, but an embodiment of the present disclosure is not limited thereto. For example, according to the thicknesses of the emission layers EML-B, EML-G and EML-R, the shapes of the quantum dots QD-C1, QD-C2 and QD-C3 included in the emission layers EML-B, EML-G and EML-R, and the average diameters of the quantum dots QD-C1, QD-C2 and QD-C3, the arrangement of the quantum dots QD-C1, QD-C2 and QD-C3 may be changed. In embodiments, the quantum dots QD-C1, QD-C2 and QD-C3 in the emission layers EML-B, EML-G and EML-R may be provided to form one layer, or provided to form a multilayer of two layers, three layers, or the like.

The first quantum dot QD-C1 of the first light emitting element ED-1 may emit blue light. The second quantum dot QD-C2 of the second light emitting element ED-2 may emit green light. The third quantum dot QD-C3 of the third light emitting element ED-3 may emit red light. Each of the quantum dots QD-C1, QD-C2 and QD-C3 may include a core and a shell surrounding the core. Accordingly, each of the quantum dots QD-C1, QD-C2 and QD-C3 may include a core-shell structure. The cores of the quantum dots QD-C1, QD-C2 and QD-C3 may include different materials from each other. Differently, the cores of the quantum dots QD-C1, QD-C2 and QD-C3 may include the same material. In embodiments, two cores selected from the cores of the quantum dots QD-C1, QD-C2 and QD-C3 may include the same material, and the remaining one core may include a different material.

In FIG. 4, the diameters of the first to third quantum dots QD-C1, QD-C2 and QD-C3 are shown to be similar, but an embodiment of the present disclosure is not limited thereto. The diameters of the first to third quantum dots QD-C1, QD-C2 and QD-C3 may be different from each other. For example, the first quantum dot QD-C1 of the first light emitting element ED-1, that emit light of a relatively short wavelength region may have a relatively smaller average diameter when compared to the second quantum dot QD-C2 of the second light emitting element ED-2 and the third quantum dot QD-C3 of the third light emitting element ED-3. The average diameter corresponds to an arithmetic average value of the particle diameters of a plurality of quantum dots. The particle diameter of the quantum dots may be an average value of the widths of the cross-sections of the quantum dot particles.

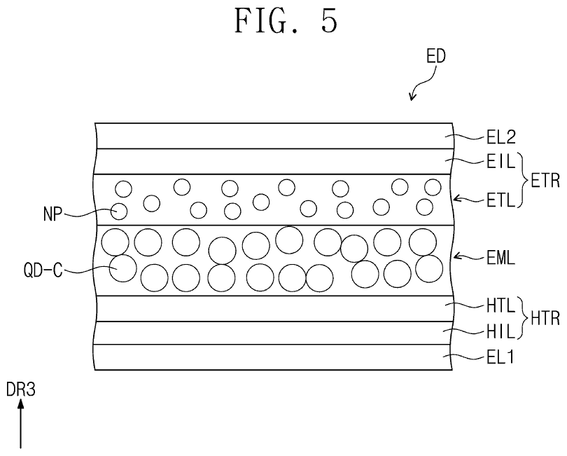

In an embodiment, the electron transport regions ETR-1, ETR-2 and ETR-3 may include a nanoparticle NP (FIG. 5) which will be further explained below. The nanoparticle NP (FIG. 5) will be explained in more detail below.

The hole transport regions HTR-1, HTR-2 and HTR-3 of the first to third light emitting elements ED-1, ED-2 and ED-3 may be in the pixel opening part OH to be divided or defined. The first light emitting element ED-1 may include the first hole transport region HTR-1, the second light emitting element ED-2 may include the second hole transport region HTR-2, and the third light emitting element ED-3 may include the third hole transport region HTR-3.

Each of the hole transport regions HTR-1, HTR-2 and HTR-3 may have a single layer formed using a single material, a single layer formed using a plurality of different materials, or a multilayer structure including a plurality of layers formed using a plurality of different materials. The thicknesses of the first to third hole transport regions HTR-1, HTR-2 and HTR-3 may be, for example, about 50 Å to about 15,000 Å. The thicknesses of the first to third hole transport regions HTR-1, HTR-2 and HTR-3 may be, for example, about 100 Å to about 10,000 Å, for example, about 100 Å to about 5,000 Å.

The first to third hole transport regions HTR-1, HTR-2 and HTR-3 may further include any suitable hole injection material and/or any suitable hole transport material. For example, the first to third hole transport regions HTR-1, HTR-2 and HTR-3 may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly (3,4-ethylenedioxythiophene)/poly (4-styrenesulfonate) (PEDOT/PSS), polyaniline/dodecylbenzenesulfonic acid (PANI/DBSA), polyaniline/camphor sulfonic acid (PANI/CSA), polyaniline/poly (4-styrenesulfonate) (PANI/PSS), N,N′-di (1-naphthalene-1-yl)-N,N′-diphenyl-benzidine (NPB), triphenylamine-containing polyetherketone (TPAPEK), 4-isopropyl-4′-methyldiphenyliodonium [tetrakis (pentafluorophenyl) borate], and/or dipyrazino [2,3-f:2′,3′-h]quinoxaline-2,3,6,7,10,11-hexacarbonitrile (HATCN).

In embodiments, the first to third hole transport regions HTR-1, HTR-2 and HTR-3 may include carbazole derivatives such as N-phenyl carbazole and/or polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris (N-carbazolyl)triphenylamine (TCTA), N,N′-di (naphthalene-1-yl)-N,N′-diphenyl-benzidine (NPB), 4,4′-cyclohexylidene bis [N,N-bis (4-methylphenyl) benzeneamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis (N-carbazolyl)benzene (mCP), or 1,3-bis(1,8-dimethyl-9H-carbazol-9-yl)benzene (mDCP), etc.

The electron transport regions ETR-1, ETR-2 and ETR-3 of the first to third light emitting elements ED-1, ED-2 and ED-3 may be provided and divided in the pixel opening part OH. The first light emitting element ED-1 may include the first electron transport region ETR-1, the second light emitting element ED-2 may include the second electron transport region ETR-2, and the third light emitting element ED-3 may include the third electron transport region ETR-3.

Each of the first to third electron transport regions ETR-1, ETR-2 and ETR-3 may have a single layer formed using a single material, a single layer formed using a plurality of different materials, or a multilayer structure having a plurality of layers formed using different materials. The thicknesses of the first to third electron transport regions ETR-1, ETR-2 and ETR-3 may be, for example, about 1000 Å to about 1500 Å.

The first to third electron transport regions ETR-1, ETR-2 and ETR-3 may further include any suitable electron injection material and/or any suitable electron transport material in addition to the above-described nanoparticle NP (FIG. 5). For example, the electron transport region ETR may include an anthracene-based compound. In embodiments, the first to third electron transport regions ETR-1, ETR-2 and ETR-3 may include, for example, tris(8-hydroxyquinolinato)aluminum (Alq3), 1,3,5-tri [(3-pyridyl)-phen-3-yl]benzene, 2,4,6-tris (3′-(pyridin-3-yl) biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl) benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato) aluminum (BAlq), berylliumbis (benzoquinolin-10-olate (Bebq₂), 9,10-di (naphthalene-2-yl) anthracene (ADN), 1,3-bis [3,5-di(pyridin-3-yl)phenyl]benzene (BmPyPhB), and mixtures thereof. Otherwise, the electron transport region ETR may include 2,9-dimethyl-4,7-diphenyl-1,10-phenanthroline (BCP), diphenyl (4-(triphenylsilyl) phenyl) phosphine oxide (TSPO1), 4,7-diphenyl-1,10-phenanthroline (Bphen), and/or the like.

The encapsulating layer TFE may include at least one inorganic layer (hereinafter, an encapsulating inorganic layer). In embodiments, the encapsulating layer TFE may include at least one organic layer (hereinafter, an encapsulating organic layer) and at least one encapsulating inorganic layer.

The encapsulating inorganic layer may protect the display element layer DP-EL from moisture/oxygen, and the encapsulating organic layer may protect the display element layer DP-EL from foreign materials such as dust particles. The encapsulating inorganic layer may include silicon nitride, silicon oxy nitride, silicon oxide, titanium oxide, and/or aluminum oxide, without specific limitation. The encapsulating organic layer may include an acrylic compound, an epoxy-based compound, etc. The encapsulating organic layer may include a photopolymerizable organic material, without specific limitation.

An optical layer PP may include a base substrate BL and a color filter layer CFL. The base substrate BL may be a member that provides a base surface where the color filter layer CFL is provided. The base substrate BL may be a glass substrate, a metal substrate, a plastic substrate, and/or the like. However, an embodiment of the present disclosure is not limited thereto, but the base substrate BL may be an inorganic layer, an organic layer or a composite material layer (e.g., including an organic material and an inorganic material).

The color filter layer CFL may include first to third filters CF-B, CF-G and CF-R. The first to third color filters CF-B, CF-G and CF-R may be respectively provided correspondingly to the first to third light emitting elements ED-1, ED-2 and ED-3. For example, the first filter CF-B may be a blue filter, the second filter CF-G may be a green filter, and the third filter CF-R may be a red filter. The first to third filters CF-B, CF-G and CF-R may be provided corresponding to the first to third pixel areas PXA-R, PXA-B and PXA-G, respectively.

Each of the first to third filters CF-B, CF-G and CF-R may include a photosensitive polymer resin and a pigment and/or dye. The first filter CF-B may include a blue pigment and/or a blue dye, the second filter CF-G may include a green pigment and/or a green dye, and the third filter CF-R may include a red pigment and/or a red dye. However, an embodiment of the present disclosure is not limited thereto, and the first filter CF-B may not include the pigment or dye. The first filter CF-B may include a photosensitive polymer resin and not include a pigment or dye. The first filter CF-B may be transparent. The first filter CF-B may be formed using a transparent photosensitive resin.

The color filter layer CFL may further include a buffer layer BFL. For example, the buffer layer BFL may be a protection layer that protects the first to third filters CF-B, CF-G and CF-R. The buffer layer BFL may be an inorganic layer including at least one inorganic material among silicon nitride, silicon oxide and silicon oxynitride. The buffer layer BFL may be formed as a single layer or a plurality of layers.

In embodiments, the second filter CF-G and the third filter CF-R may be yellow filters. The second filter CF-G and the third filter CF-R may be provided in one body without distinction.

In embodiments, the color filter layer CFL may further include a light blocking part. The light blocking part may be a black matrix. The light blocking part may be formed by including an organic light blocking material and/or an inorganic light blocking material, including a black pigment and/or black dye. The light blocking part may prevent or reduce light leakage and may divide the boundaries among adjacent filters CF-B, CF-G and CF-R.

FIG. 5 is a cross-sectional view showing a light emitting element ED of an embodiment. The light emitting element ED, explained referring to FIG. 5 may be applied to at least one among the first to third light emitting elements ED-1, ED-2 and ED-3, shown in FIG. 4 in the same manner.

Referring to FIG. 5, the light emitting element ED may include a first electrode EL1, a hole transport region HTR, an emission layer EML, an electron transport region ETR, and a second electrode EL2, stacked in order. The hole transport region HTR may include a hole injection layer HIL and a hole transport layer HTL. The hole injection layer HIL may be on the first electrode EL1, and the hole transport layer HTL may be on the hole injection layer HIL. The electron transport region ETR may include an electron transport layer ETL and an electron injection layer EIL. The electron injection layer EIL may be on the electron transport layer ETL, and the second electrode EL2 may be on the electron injection layer EIL. In the light emitting element ED, the electron transport region ETR may include the nanoparticle NP of an embodiment.

The electron transport region ETR may include the nanoparticle NP of an embodiment.

In embodiments, the electron transport layer ETL may include the nanoparticle NP of an embodiment. In embodiments, the electron transport layer ETL and the electron injection layer EIL may include the nanoparticle NP of an embodiment. The electron transport region ETR including the nanoparticle NP of an embodiment may contribute to the increase of electron injection properties and/or electron transport properties and thereby contribute the improvement of the light efficiency of the light emitting element ED.

The emission layer EML may include a quantum dot QD-C. Hereinafter, the same explanation on the first to third quantum dots QD-C1, QD-C2 and QD-C3, shown in FIG. 4 will be applied to the quantum dot QD-C.

In the description, the quantum dot QD-C refers to the crystal of a semiconductor compound. The quantum dot QD-C may emit light of various suitable wavelengths according to the size of the crystal. The diameter of the quantum dot QD-C may be, for example, about 1 nm to about 10 nm.

The quantum dot QD-C may be synthesized by a chemical bath deposition, a metal organic chemical vapor deposition, a molecular beam epitaxy and/or a similar process therewith. The chemical bath deposition is a method of growing quantum dot QD-C particle crystal after mixing together an organic solvent and a precursor material. During the growth of the crystal, the organic solvent naturally plays the role of a dispersant coordinated at the surface of the quantum dot QD-C crystal and may control the growth of the crystal. Accordingly, the chemical bath deposition is more favorable than a vapor deposition method such as a metal organic chemical vapor deposition (MOCVD) and a molecular beam epitaxy (MBE), and may control the growth of the quantum dot QD-C particle through a low cost process.

The quantum dot may include II-VI group semiconductor compounds, I-II-VI group semiconductor compounds, II-IV-VI group compounds, I-II-IV-VI group semiconductor compounds, III-V group semiconductor compounds, III-VI group semiconductor compounds, I-III-VI group semiconductor compounds, IV-VI group semiconductor compounds, II-IV-V group semiconductor compounds, IV group elements or compounds, and arbitrary combinations thereof. In the description, the term “group” means the group in an IUPAC periodic table.

Examples of the II-VI group compound may include a binary compound such as CdS, CdSe, CdTe, ZnS, ZnSe, ZnTe, ZnO, HgS, HgSe, HgTe, MgSe, and MgS, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS, a quaternary compound such as CdZnSeS, CdZnSeTe, CdZnSTe, CdHgSeS, CdHgSeTe, CdHgSTe, HgZnSeS, HgZnSeTe, and HgZnSTe, or suitable combinations thereof. In embodiments, the II-VI group semiconductor compound may further include a metal in group I and/or an element in group IV. The I-II-VI group compound may be selected from CuSnS or CuZnS, and the II-IV-VI group compound may include ZnSnS, etc. The I-II-IV-VI group compound may be selected from quaternary compounds selected from the group consisting of Cu₂ZnSnS₂, Cu₂ZnSnS₄, Cu₂ZnSnSe₄, Ag₂ZnSnS₂ and mixtures thereof.

Examples of the III-V group semiconductor compound may include a binary compound such as GaN, GaP, GaAs, GaSb, AlN, AlP, AlAs, AlSb, InN, InP, InAs, and InSb, a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and InPSb, a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, or suitable combinations thereof. In embodiments, the III-V group semiconductor compound may further include a II group element. Examples of the III-V group semiconductor compound including the element in group II may include InZnP, InGaZnP, InAlZnP, etc.

Examples of the III-VI group semiconductor compound may include a binary compound such as GaS, Ga₂S₃, GaSe, Ga₂Se₃, GaTe, InS, InSe, In₂Se₃, and InTe, a ternary compound such as InGaS₃, and InGaSe₃, or suitable combinations thereof.

Examples of the I-III-VI group semiconductor compound may include a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and AgAlO₂, a quaternary compound such as AgInGaS₂, and CuInGaS₂, or suitable combinations thereof.

Examples of the IV-VI group semiconductor compound may include a binary compound such as SnS, SnSe, SnTe, PbS, PbSe, and PbTe, a ternary compound such as SnSeS, SnSeTe, SnSTe, PbSeS, PbSeTe, PbSTe, SnPbS, SnPbSe, and SnPbTe, a quaternary compound such as SnPbSSe, SnPbSeTe, and SnPbSTe, or suitable combinations thereof.

Examples of the II-IV-V group semiconductor compound may be a ternary compound selected from the group consisting of ZnSnP, ZnSnP₂, ZnSnAs₂, ZnGeP₂, ZnGeAs₂, CdSnP₂, CdGeP₂ and mixtures thereof.

The IV group element or compound may include a single element compound such as Si, and Ge, a binary compound such as SiC, and SiGe, or suitable combinations thereof.

Each element included in a polynary compound such as the binary compound, the ternary compound and the quaternary compound may be present at uniform concentration or non-uniform concentration in a particle. In embodiments, the chemical formulae mean the types (or kinds) of elements included in the compound, and the element ratio in the compound may be different. For example, AgInGaS₂ may mean AgInₓGa₁₋ₓS₂ (x is a real number of 0 to 1).

In embodiments, the quantum dot QD-C may have a single structure in which the concentration of each element included in the quantum dot QD-C is uniform (or substantially uniform), or a double structure of a core-shell. For example, the material included in the core and the material included in the shell may be different.

The shell of the quantum dot QD-C may play the role of a protection layer for preventing or reducing the chemical deformation of the core and maintaining semiconductor properties and/or a charging layer for providing the quantum dot with electrophoresis properties. The shell may be a single layer or a multilayer. In the core/shell structure, the shell may have a concentration gradient in which the concentration of an element present in the shell is reduced along a direction toward the core.

Examples of the shell of the quantum dot QD-C may include a metal and/or non-metal oxide, a semiconductor compound, or combinations thereof. Examples of the metal and/or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, a ternary compound such as MgAl₂O₄, CoFe₂O₄, NiFe₂O₄ and CoMn₂O₄, or suitable combinations thereof. Examples of the semiconductor compound may include III-VI group semiconductor compounds, II-VI group semiconductor compounds, III-V group semiconductor compounds, III-VI group semiconductor compounds, I-III-VI group semiconductor compounds, IV-VI group semiconductor compounds, or suitable combinations thereof, as described in this description. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AIP, AISb, etc., or suitable combinations thereof.

Each element included in the polynary compound such as the binary compound, and the ternary compound may be present at uniform concentration or non-uniform concentration in a particle. In embodiments, the chemical formulae mean the types (or kinds) of elements included in the compound, and the element ratio in the compound may be different.

The quantum dot may have a full width of half maximum (FWHM) of an emission wavelength spectrum of about 45 nm or less, about 40 nm or less, or, for example, about 30 nm or less. Within the above ranges, color purity and/or color reproducibility may be improved. In embodiments, light emitted via such quantum dot is emitted in all (or substantially all) directions, and light view angle may be improved.

In embodiments, the type (or kind) of the quantum dot may be any suitable type (or kind) generally used in this field and is not specifically limited, but may be, for example, spherical, pyramidal, multi-arm, and/or cubic nanoparticles, nanotubes, nanowires, nanofibers, nanoplate particles, etc. may be used.

By controlling the size of the quantum dot and/or by controlling the element ratio in the quantum dot compound, energy band gap may be controlled, and various suitable wavelength bands of light may be obtained from an emission layer EML including the quantum dot. Accordingly, by using such quantum dots (by using quantum dots having different sizes and/or by controlling an element ratio in a quantum dot compound differently), a light emitting element that emits various suitable wavelengths of light may be accomplished. In embodiments, the size of the quantum dot and/or the element ratio in the quantum dot compound may be selected to emit red, green and/or blue light. In embodiments, the quantum dots may be provided to combine various suitable emission colors to emit white light.

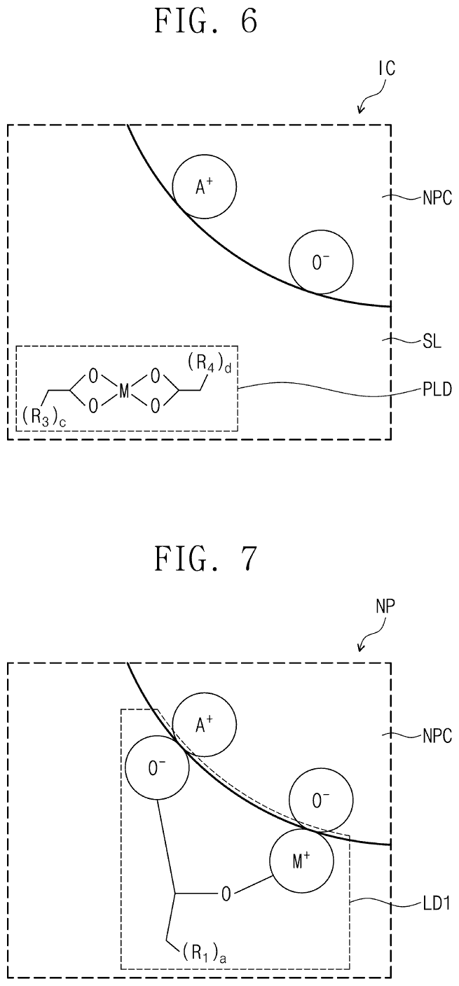

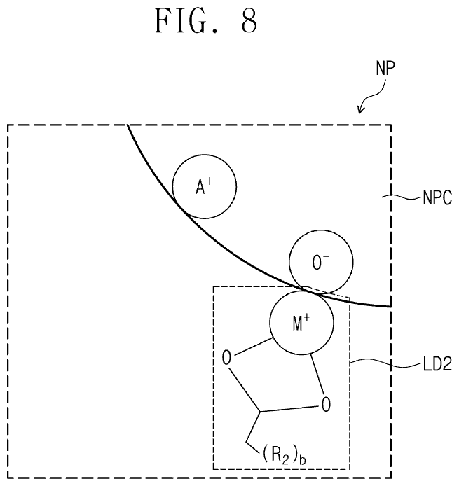

FIG. 6 shows a portion of an ink composition according to an embodiment. FIG. 7 and FIG. 8 show portions of nanoparticles according to embodiments.

Referring to FIG. 6, the ink composition IC of an embodiment includes a nanoparticle core NPC, a preliminary ligand PLD, and a solvent SL. The nanoparticle core NPC includes a core compound represented by Formula 1. The core compound includes a core metal element A and an oxygen atom.

AₓO_{y} (1)

In Formula 1, the core metal element A is Zn, or Sn. “x”, and “y: are each independently an integer of 1 to 5. For example, the core compound may be one among SnO₂ and ZnO.

The preliminary ligand PLD is represented by Formula 4. The preliminary ligand PLD includes a substituted or unsubstituted carboxylate and a ligand metal element M. The ligand metal element M is bonded to the oxygen atom included in the carboxylate.

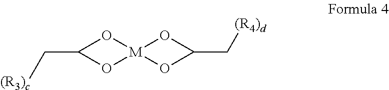

In Formula 4, the ligand metal element M is one among Li, Na, K, Rb, Cs, Be, Ca, Sr, and Ba. The standard reduction potential of the ligand metal element M may be smaller than the standard reduction potential of the core metal element A. The absolute value of the standard reduction potential of the ligand metal element M may be greater than the absolute value of the standard reduction potential of the core metal element A. For example, the ligand metal element M may be Ca. R₃ and R₄ are each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₃ and R₄ may be each independently an unsubstituted methyl group. In embodiments, R₃ and R₄ may be each independently an unsubstituted hexadecene ((Z)-hexadec-7-ene). “c” and “d” are each independently an integer of 0 to 3. For example, “c” may be 2, and “d” may be 1. In an embodiment, R₃ and R₄ may be each independently a substituted or unsubstituted alkyl group of 1 to 5 carbon atoms. For example, R₃ and R₄ may be each an unsubstituted methyl group. In an embodiment, R₃ and R₄ may be each independently a substituted or unsubstituted alkyl group of 6 to 20 carbon atoms. For example, R3 and R4 may be each an unsubstituted n-heptadecane.

If R₃ and R₄ are each independently a substituted or unsubstituted alkyl group of 1 to 5 carbon atoms, the solvent SL may include a water-soluble solvent. The weight ratio of the nanoparticle core NPC to the water-soluble solvent may be about 1% to about 10%. For example, the weight ratio of the nanoparticle core NPC to the water-soluble solvent may be about 3%. The solvent SL including the water-soluble solvent may include a first solvent compound represented by Formula 5.

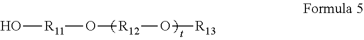

In Formula 5, R₁₁ and R₁₂ may be each independently a substituted or unsubstituted alkylene group of 1 to 4 carbon atoms. For example, R₁₁ may be an unsubstituted ethylene group, or an unsubstituted propylene group. For example, R₁₂ may be an unsubstituted ethylene group, or an unsubstituted propylene group. R₁₃ may be a substituted or unsubstituted alkyl group of 1 to 4 carbon atoms. For example, R₁₃ may be an unsubstituted isopropylene group, an unsubstituted butyl group, or an unsubstituted t-butyl group. In embodiments, “t” may be 1 or 2. The first solvent compound may include at least one among diethylene glycol t-butyl ether (DGtBE), tripropylene glycol monobutyl ether (TPGBE), and triethylene glycol monoisopropyl ether (TGIPE).

If R₃ and R₄ are each independently a substituted or unsubstituted alkyl group of 6 to 20 carbon atoms, the solvent SL may include at least one among cyclohexylbenzene (CHB) and hexadecane.

The ink composition IC shown in FIG. 6 may be used as a material for forming the electron transport region ETR (FIG. 5). A method of forming the electron transport region ETR (FIG. 5) may include forming each nanoparticle NP (FIG. 7 and FIG. 8) by bonding ligands LD1 and LD2 (FIG. 7 and FIG. 8) to the surface of each nanoparticle core NPC, providing an emission layer EML (FIG. 5) with each ink composition IC in which each the nanoparticle NP (FIG. 7 and FIG. 8) is formed, and drying a solvent SL.

Referring to FIG. 5, FIG. 7 and FIG. 8 together, the nanoparticle NP may include a nanoparticle core NPC including a core compound represented by Formula 1 and a ligand LD1 or LD2, bonded to the surface of the nanoparticle core NPC and represented by Formula 2 or Formula 3. The electron transport region ETR of a display device DD (FIG. 4) and/or a light emitting element ED may include the nanoparticle NP. In an embodiment, the electron transport layer ETL may include the nanoparticle NP. The same contents explained with reference to FIG. 6 may be applied to the core compound and the nanoparticle core NPC. The ligands LD1 and LD2 may include a first ligand LD1 and a second ligand LD2. The first ligand LD1 may be represented by Formula 2, and the second ligand LD2 may be represented by Formula 3. The ligands LD1 and LD2 include a substituted or unsubstituted carboxylate and the ligand metal element M. The ligand metal element M is bonded to the oxygen atom included in the carboxylate.

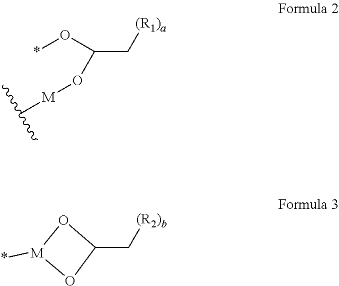

In Formula 2 and Formula 3, M is one among Li, Na, K, Rb, Cs, Be, Ca, Sr, and Ba. For example, M may be Ca. R₁ and R₂ are each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₁ may be an unsubstituted methyl group. For example, R₂ may be an unsubstituted n-heptadecane group. “a” and “b” are each independently an integer of 0 to 3. For example, “a” may be 1. For example, “b” may be 1. “ [symbol] ” and

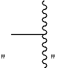

are positions connected with the nanoparticle core.

The ligands LD1 and LD2 may be formed through the decomposition of the above-described preliminary ligand PLD (FIG. 6). The ligands LD1 and LD2 may make chemical bonds to the core compound distributed at the surface of the nanoparticle core NPC. For example, the ligands LD1 and LD2 may make ionic bonds to the core compound distributed at the surface of the nanoparticle core NPC. An oxygen atom connected with “ [symbol] ” of the first ligand LD1 represented by Formula 2 may have a negative charge, and may make an ionic bond with the core metal element A ion of the core compound having a positive charge. The ligand metal element M connected with

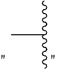

of the first ligand LD1 represented by Formula 2 may have a positive charge and may make an ionic bond with the oxygen anion of the core compound. The ligand metal element M of the second ligand LD2 represented by Formula 3 may have a positive charge and may make an ionic bond with the oxygen anion of the core compound.

During the continuous driving of a light emitting element ED or a display device DD (FIG. 4), electrons injected from an electron injection layer EIL toward an electron transport layer ETL may reduce a core metal element A included in the electron transport layer ETL and increase the mobility of the electrons. The core metal element A reduced by the electrons have defects that degrade the increasing function of the mobility of the electrons in contrast to the mobility prior to the reduction. In order to prevent or reduce such defects, in the present disclosure, the ligands LD1 and LD2 including the ligand metal element M cover the nanoparticle core NPC. The standard reduction potential of the ligand metal element M may be smaller than the standard reduction potential of the core metal element A. In embodiments, the ligand metal element M is more difficult to be reduced than the core metal element A. Accordingly, if the ligands LD1 and LD2 cover the surface of the nanoparticle core NPC, the reduction of the core metal element A by the electrons injected during the driving of a light emitting element ED or a display device DD (FIG. 4) may be prevented or reduced. The ligands LD1 and LD2 may be provided in plural and may cover the surface of the nanoparticle core NPC, to prevent or reduce the reduction of the metal element A of the nanoparticle core NPC by the electrons.

The nanoparticle core NPC may be doped with a metal element. The nanoparticle core NPC may be doped with at least one among Zn, Mg, Li, Na, Ni, and Cu. If the nanoparticle core NPC is doped with the metal element, the metal element surrounding the nanoparticle core NPC may be reduced first compared to the core metal element A of the nanoparticle core NPC, and the increasing function of the electron mobility of the core metal element A may be preserved.

Hereinafter, the nanoparticle according to an embodiment of the present disclosure and the light emitting element of an embodiment will be explained in more detail, while referring to an example and a comparative example. The example shown below is an illustration for assisting the understanding of embodiments of the present disclosure, and the scope of the present disclosure is not limited thereto.

### EXAMPLE

### 1. Manufacture and Evaluation of Light Emitting Element

### (1) Manufacture of Light Emitting Element

A light emitting element of an embodiment, including the nanoparticle of an embodiment in an electron transport region was manufactured by a method below.

### Manufacture of Light Emitting Element

A substrate on which ITO was deposited as an anode was cut into a size of 50 mm×50 mm×0.5 mm, cleansed by ultrasonic waves using isopropyl alcohol and pure water for 5 minutes each, irradiated with ultraviolet light for about 30 minutes, and exposed to ozone for cleansing, and the ITO substrate was installed in a vacuum deposition apparatus.

On the ITO substrate, poly (3,4-ethylenedioxythiophene)/poly (4-styrenesulfonate) (PEDOT/PSS) was deposited to form a hole injection layer having a thickness of about 600 Å, and on the hole injection layer, poly[(9,9-dioctylfluorenyl-2,7-diyl)-co-(4,4′-(N-(4-sec-butylphenyl) diphenylamine)] (TFB) was vacuum deposited to form a hole transport layer with a thickness of about 400 Å.

On the hole transport layer, quantum dots having a structure of InP/ZnSe/ZnS were spin-coated to a thickness of about 200 Å to form an emission layer, and on the emission layer, the nanoparticles of an embodiment were spin-coated to form an electron transport layer having a thickness of about 280 Å. On the electron transport layer, Al was deposited to form a cathode having a thickness of about 1000 Å, to manufacture a light emitting element.

The nanoparticles of the Example were formed by the process below. Tin (IV) acetate (1 mmol), oleic acid (3.3 ml), oleylamine (3.3 ml) and xylene (30 ml) were added to a reactor and stirred for about 30 minutes under a vacuum atmosphere. After providing a N₂ atmosphere to the reactor, the temperature was elevated to about 100° C., and the reactor was maintained for about 30 minutes. To a stabilized Sn⁴⁺ mixture, DI water (1 ml) was rapidly injected, and the reaction was carried out for about 5 hours. After finishing the reaction, the temperature of the mixture was reduced to room temperature, and an excessive amount of ethanol was injected thereto. The SnO₂ thus synthesized was precipitated and dispersed in hexane to synthesize SnO₂ seeds. For the additional growth of SnO₂, Tin (IV) acetate (1 mmol), oleic acid (3.3 ml), and trioctylamine (10 ml) were added to the reactor, the temperature was elevated to about 120° C., and stirring was performed for about 30 minutes under a vacuum atmosphere. After providing a N₂ atmosphere to the reactor, the SnO₂ seeds were injected, and the reaction was continued for about 1 hour. After finishing the reaction, the temperature of a SnO₂ solution was reduced to room temperature, then, washed using hexane and ethanol twice, and dispersed in cyclohexylbenzene. Ca-acetate (1 mmol) and oleic acid (2 mmol) were mixed together with a 1-octadecene solvent, and then, heated at 200° C. to prepare Ca-oleate. Then, the temperature was reduced to 120° C., the synthesized tin oxide was injected thereto, vacuum treatment was performed for about 10 minutes, and the reaction was carried out for about 30 minutes.

The nanoparticles of the Comparative Example were formed by a process below. Zn-acetate (1 mmol) and magnesium acetate (0.2 mmol) were dissolved in DMSO (10 ml) to prepare Solution A. Trimethyl ammonium hydroxide (1 mmol) was dissolved in ethanol (5 ml) to prepare Solution B. Solution B was slowly injected to Solution A and reacted at about 4° C. for about 1 hour. After finishing the reaction, acetone (10 ml) and octane (5 ml) were added, and centrifugal separation was carried out to precipitate nanoparticles. The nanoparticles were re-dispersed in ethanol.

### (2) Evaluation of Properties of Light Emitting Element

### Evaluation of Properties of Light Emitting Element

The driving voltage (V, @5 mA/cm²), element efficiency (Cd/A, @2000 nit) and element lifetime (h, @T90) of the light emitting elements of the Example and the Comparative Example were evaluated. In Table 1, the evaluation results of the light emitting elements manufactured in the Example and the Comparative Example are shown. In order to evaluate the properties of the light emitting elements manufactured in the Example and the Comparative Example, a driving voltage (V) at a current density of about 5 mA/cm², emission efficiency (Cd/A) at about 2000 nit were measured, and the absolute time taken from an initial luminance to 90% luminance was measured as the lifetime (@T90).

TABLE 1

| | Driving voltage, | Efficiency, | Lifetime, |
|---|---|---|---|
| | V (@5 mA/cm²) | Cd/A (@2000 nit) | h (@T90) |
| Comparative Example | 5.2 | 47.2 | 650 |
| Example | 5.1 | 59.8 | 1080 |

Referring to the results of Table 1, it can be seen that the light emitting element of the Example, using the nanoparticles according to an embodiment of the present disclosure as the material of an electron transport layer showed a relatively low driving voltage, high emission efficiency and long element lifetime compared to the light emitting element of the Comparative Example. The core metal elements included in the light emitting elements of the Example and the Comparative Example play the role of controlling the mobility of electrons injected during driving of the light emitting elements. If the core metal element is reduced by the electrons, the function of the core metal element controlling the electron mobility may be deteriorated. If the electron mobility is not controlled, and the electron mobility is reduced, the current density may decrease, and the electric field value of the electron transport layer may increase. If the electric field value of the electron transport layer increases, the deterioration of the light emitting element may be accelerated, and thus, the lifetime may decrease, and emission efficiency may decrease. In the light emitting element of the Example, a ligand including a ligand metal element having a lower standard reduction potential than the core metal element A covers a nanoparticle core. Accordingly, the reduction of the core metal element A by electrons injected during driving of the light emitting element of the Example may be prevented or reduced, the electron mobility may be easily controlled, and the efficiency and lifetime of the light emitting element may be improved. However, in the light emitting element of the Comparative Example, the core metal element A and the ligand metal element are the same (Zn), the standard reduction potential values are the same, and though the ligand covers the nanoparticle core, the preventing or reducing function of the reduction of the core metal element may be deteriorated. Accordingly, the mobility of the electrons cannot be controlled, the mobility of the electrons may be reduced, and the emission efficiency and the lifetime may be reduced.

The light emitting element of an embodiment may show improved element properties of high efficiency and long lifetime.

The ink composition of an embodiment may contribute to the increase of efficiency and lifetime of a light emitting element.

The display device of an embodiment may include a light emitting element having excellent efficiency and lifetime.

Although example embodiments of the present disclosure have been described, it is understood that the present disclosure should not be limited to these embodiments, but various changes and modifications can be made by one ordinary skilled in the art within the spirit and scope of the present disclosure as hereinafter claimed.

What is claimed is:

1. A light emitting element, comprising:
a first electrode;
a hole transport region on the first electrode;
an emission layer on the hole transport region;
an electron transport region on the emission layer; and
a second electrode on the electron transport region,
wherein the electron transport region comprises a nanoparticle comprising a nanoparticle core, and a ligand,
the nanoparticle core comprises a core compound represented by the following Formula 1, and
the ligand is bonded to the surface of the nanoparticle core, and represented by the following Formula 2 or Formula 3: 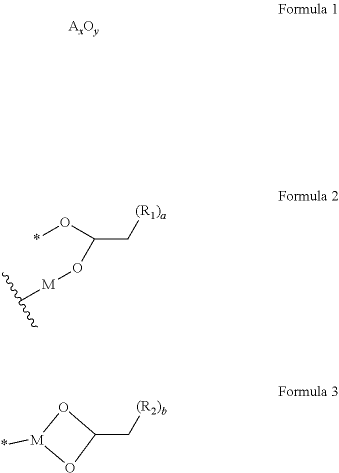
in Formula 1,
A is Zn, or Sn, and
“x”, and “y” are each independently an integer of 1 to 5, in Formula 2,
M is one among Li, Na, K, Rb, Cs, Be, Ca, Sr, and Ba,
R₁ is a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms,
“a” is an integer of 0 to 3, and
“ [symbol] ”, and 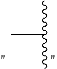
are each a position connected with the nanoparticle core, and
in Formula 3,
R2 is a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms,
M is the same as defined with respect to Formula 2,
“b” is an integer of 0 to 3, and
“ [symbol] ” is a position connected with the nanoparticle core.

2. The light emitting element of claim 1, wherein:
the electron transport region comprises:
an electron transport layer on the emission layer; and
an electron injection layer on the electron transport layer, and
the electron transport layer comprises the nanoparticle.

3. The light emitting element of claim 1, wherein the nanoparticle core is doped with a metal element.

4. The light emitting element of claim 3, wherein the metal element is at least one among Zn, Mg, Li, Na, Ni, and Cu.

5. The light emitting element of claim 1, wherein the emission layer comprises a quantum dot.

6. The light emitting element of claim 1, wherein, in Formula 1, “x” is 1, and “y” is 2.

7. The light emitting element of claim 1, wherein:
in Formula 1,
“A” is Sn, and
in Formula 2 and Formula 3,
M is Ca.

8. The light emitting element of claim 1, wherein:
if the ligand is represented by Formula 2,
R₁ is a substituted or unsubstituted alkyl group of 1 to 5 carbon atoms, and if the ligand is represented by Formula 3,
R₂ is a substituted or unsubstituted alkyl group of 1 to 5 carbon atoms.

9. The light emitting element of claim 1, wherein:
if the ligand is represented by Formula 2,
R₁ is a substituted or unsubstituted alkyl group of 6 to 20 carbon atoms, and if the ligand is represented by Formula 3,
R₂ is a substituted or unsubstituted alkyl group of 6 to 20 carbon atoms.

10. An ink composition comprising:
a nanoparticle core comprising a core compound represented by the following Formula 1;
a preliminary ligand represented by the following Formula 4; and
a solvent in which the nanoparticle core and the preliminary ligand are dispersed: 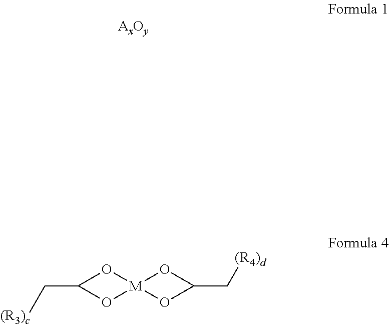
in Formula 1,
A is Zn, or Sn, and
“x”, and “y” are each independently an integer of 1 to 5,
in Formula 4,
M is one among Li, Na, K, Rb, Cs, Be, Ca, Sr, and Ba,
R₃ and R₄ are each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and
“c” and “d” are each independently an integer of 0 to 3.

11. The ink composition of claim 10, wherein, in Formula 4, R₃ and R₄ are each independently a substituted or unsubstituted alkyl group of 1 to 5 carbon atoms.

12. The ink composition of claim 11, wherein the solvent comprises a water-soluble solvent.

13. The ink composition of claim 12, wherein a weight ratio of the nanoparticle core to the water-soluble solvent is about 1% to about 10%.

14. The ink composition of claim 12, wherein the water-soluble solvent comprises a first solvent compound represented by the following Formula 5: 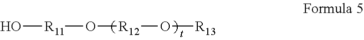
in Formula 5,
R₁₁ and R₁₂ are each independently a substituted or unsubstituted alkylene group of 1 to 4 carbon atoms,
R₁₃ is a substituted or unsubstituted alkyl group of 1 to 4 carbon atoms, and “t” is 1 or 2.

15. The ink composition of claim 14, wherein the first solvent compound comprises at least one among diethylene glycol t-butyl ether (DGtBE), tripropylene glycol monobutyl ether (TPGBE), and triethylene glycol monoisopropyl ether (TGIPE).

16. The ink composition of claim 10, wherein, in Formula 4, R₃ and R₄ are each independently a substituted or unsubstituted alkyl group of 6 to 20 carbon atoms.

17. The ink composition of claim 16, wherein the solvent comprises at least one among cyclohexylbenzene (CHB) and hexadecane.

18. A display device comprising:
a base layer;
a circuit layer on the base layer; and
a display element layer on the circuit layer and comprising a light emitting element,
wherein:
the light emitting element comprises a first electrode, a second electrode on the first electrode, and an electron transport region between the first electrode and the second electrode,
the electron transport region comprises a nanoparticle comprising a nanoparticle core, and a ligand,
the nanoparticle core comprises a core compound represented by the following Formula 1, and
the ligand is bonded to the surface of the nanoparticle core and represented by the following Formula 2 or Formula 3: 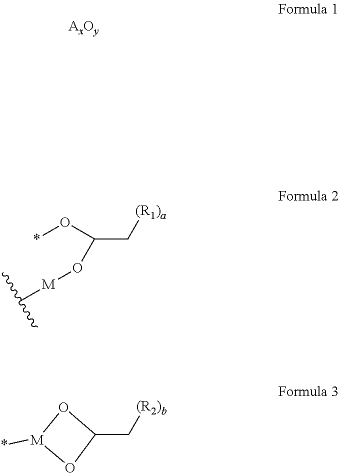
in Formula 1,
A is Zn, or Sn, and
“x”, and “y” are each independently an integer of 1 to 5, in Formula 2,
M is one among Li, Na, K, Rb, Cs, Be, Ca, Sr, and Ba,
R₁ is a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms,
“a” is an integer of 0 to 3, and
“ [symbol] ”, and 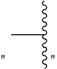
are each a position connected with the nanoparticle core, and
in Formula 3,
R₂ is a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms,
M is the same as defined with respect to Formula 2,
“b” is an integer of 0 to 3, and
“ [symbol] ” is a position connected with the nanoparticle core.

19. The display device of claim 18, wherein:
the light emitting element further comprises:
a hole transport region on the first electrode; and
an emission layer between the hole transport region and the electron transport region, and
the emission layer comprises a quantum dot.

20. The display device of claim 19, wherein:
the electron transport region comprises:
an electron transport layer on the emission layer; and
an electron injection layer on the electron transport layer, and
the electron transport layer comprises the nanoparticle.
